(19) United States
(12) Patent Application Publication
(10) Pub. No.: US 2013/0221504 A1
(43) Pub. Date: Aug. 29, 2013

(54) SEMICONDUCTOR MODULE AND METHOD OF MANUFACTURING A SEMICONDUCTOR MODULE

(71) Applicant: ABB Research Ltd, (US)

(72) Inventors: Nicola SCHULZ, Turgi (CH); Samuel HARTMANN, Staufen (CH)

(73) Assignee: ABB Research Ltd, Zurich (CH)

(21) Appl. No.: 13/861,027

(22) Filed: Apr. 11, 2013

Related U.S. Application Data
(63) Continuation of application No. PCT/EP2011/067558, filed on Oct. 7, 2011.

(30) Foreign Application Priority Data
Oct. 13, 2010 (EP) 10187399.0

(51) Int. Cl. H01L 23/495; H01L 23/00

(52) U.S. Cl. CPC H01L 23/49517; H01L 24/80
USPC 257/668; 228/110.1

(57) ABSTRACT

An exemplary semiconductor module includes a substrate formed of a ceramic insulator, and at least one metallic layer formed on the substrate. The metallic layer includes a deepening for placing and fixing a contact element. The contact element is at least partially “L”-shaped and includes a first arm for fixing the contact element at the deepening, and a second arm for interconnecting the contact element with an external device. The deepening has a horizontal dimension which is about ≦0.5 mm bigger than the horizontal dimension of the contact element.

### RELATED APPLICATION(S)

This application claims priority as a continuation application under 35 U.S.C. §120 to PCT/EP2011/067558, which was filed as an International Application on Oct. 7, 2011 designating the U.S., and which claims priority to European Application EP 10187399.0 filed in Europe on Oct. 13, 2010. The content of each prior application is hereby incorporated by reference in its entirety.

### FIELD

The disclosure relates to a semiconductor module and to a method of manufacturing a semiconductor module.

### BACKGROUND INFORMATION

A variety of semiconductor modules are known and used in many different electronic devices. For forming or manufacturing a semiconductor module, different electric parts have to be contacted with each other to provide an interlinked internal structure. Additionally, an external contact is provided to connect one or more electric parts of the semiconductor module to an external contact device.

As an example, to achieve an external electrical contact with the semiconductor module, it is known to provide a terminal as a contact element and to solder it on top of a metallization of a ceramic substrate. A drawback of the known soldering technique is a limited reliability under thermal and mechanical cycling of the soldered connection between terminal and substrate. Therefore, the connection and thus the whole semiconductor module can have a limited lifetime.

Furthermore, soldered connections can only withstand limited operation temperatures. For example, temperatures of 125° C. should not be exceeded for providing safe and reliable operation conditions in some cases.

It is therefore known to overcome this by replacing the soldered connection between one or more contacts of a semiconductor module by a welded connection. For example, ultrasonic waves, or energy respectively, are used for forming a welded connection.

In W. Rusche et al., Ultrasonic Metal Welding, Bodo's Power Magazine, Oct 2008, p. 40-41, for example, it is described to use ultrasonic metal welding for the internal contact within power modules. For example, it is described that a welding tool induces pressure and ultrasonic energy in a movable joining partner.

In case such a technique is used, ultrasonic waves can be generated in the horizontal plane, in an exemplary manner generated by a sonotrode. Due to the horizontal oscillations of the sonotrode, a force parallel to the oscillation amplitude can act on the contact element. Consequently, there can be the risk of the contact element to move in the horizontal plane. This can lead to the disadvantage that the position in which the contact element is welded may not be the intended position. Therefore, the formed semiconductor module can be unusable. Additionally, there is a risk of the contact element to be deformed and hence mechanically weakened while it is moving, or slipping, respectively. This, again, can lead to the disadvantage of the formed semiconductor module being unusable. Furthermore, the welding process becomes irreproducible.

To avoid these disadvantages, it can be possible to use stronger welding parameters. In detail, it is possible to use a higher welding energy and/or a higher pressing force. This, however, can lead to damages of the contact region where the contact element is welded to, or to the contact element itself.

WO 2007/033829 A2 discloses a power semiconductor module and a method for the production thereof. According to WO 2007/033829 A2, contacts are formed via ultrasonic welding by virtue of a sonotrode. The ultrasonic welding operation can also be used for joining the contact regions with the contact ends and consequently for joining the contacts and the foot regions of the power semiconductor module. For example, a sonotrode is brought to a contact end of a contact element, wherein the latter is pressed to the contact region to be connected. By introducing ultrasonic energy into the interface between the contact element and the substrate, the foot can be welded onto the substrate. In carrying out this step, a holding and positioning device holds the contact element in place to avoid the latter to move in a horizontal plane.

Such a holding and positioning element, however, can lead to the process becoming more complex and thus the necessity of rather complex apparatus specifications.

EP 1 711 040 A1 discloses a circuit device in which a semiconductor and a bus bar are bonded to a ceramic base board. According to EP 1 711 040 A1, a wiring layer is provided on the substrate on a part of which a coating metal layer is formed to provide a region in which the wiring layer is coated. Additionally, an exposing region is provided in which the wiring layer is exposed. The semiconductor is connected to the coated region whereas the bus bar is directly connected to the wiring layer within the exposing region.

According to EP 1 711 040 A1, the exposing region is determined to have an appropriate margin in consideration of variations of a contact area of the end portion of the bus bar. Consequently, this exposing area is adapted for allowing different bus bars with different shapes and dimensions to be fixed.

### SUMMARY

An exemplary semiconductor module is disclosed, comprising: a substrate formed of a ceramic insulator; at least one metallic layer formed on the substrate; and a contact element, the contact element being at least partially “L”-shaped and including a first arm for fixing the contact element at the deepening, and a second arm for interconnecting the contact element with an external device, wherein the at least one metallic layer includes a deepening portion for placing and fixing the contact element, wherein the deepening portion has a horizontal dimension which is about ≦0.5 mm bigger than a horizontal dimension of the contact element.

An exemplary method of manufacturing a semiconductor module, comprising: bringing into contact a contact element and a metallic layer, the contact element being at least partially “L”-shaped and including a first arm for fixing the contact element at a deepening, and a second arm for interconnecting the contact element, wherein the metallic layer includes a deepening portion for placing the contact element, wherein the deepening has a horizontal dimension which is about ≦0.5 mm bigger than the horizontal dimension of the contact element; pressing the contact element onto the metallic layer at the deepening; and applying ultrasonic energy to the interface of the contact element and the metallic layer for welding the contact element onto the metallic layer.

An exemplary semiconductor module, comprising: a substrate formed of a ceramic insulator; at least one metallic layer formed on the substrate; and a contact element having a first arm that extends in a first direction and second arm connected to the first arm that extends in a second direction, wherein the at least one metallic layer includes a depression configured to receive the first arm of the contact element, the depression having a horizontal dimension which is about ≦0.5 mm bigger than a horizontal dimension of the contact element.

### BRIEF DESCRIPTION OF THE DRAWINGS

Additional features, characteristics and advantages of the subject-matter of the disclosure are disclosed in the Figures and the following description of the respective Figures and examples, which can, in an exemplary fashion- shows exemplary embodiments and examples of semiconductor modules according to the disclosure.

Exemplary embodiments of the disclosure are explained in more detail below on the basis of the accompanying drawing, in which:

FIG. 1 shows a sectional side view of an arrangement of a semiconductor module according to an exemplary embodiment of the disclosure;

FIG. 2 shows a partial sectional side view of an exemplary embodiment of a semiconductor module according to the disclosure;

FIG. 3 shows a partial sectional side view of an exemplary embodiment of a semiconductor module according to the disclosure;

FIG. 4 shows a partial sectional side view of an exemplary embodiment of a semiconductor module not being part of the disclosure;

FIG. 5 shows a partial sectional side view of an exemplary embodiment of a semiconductor module according to the disclosure;

FIG. 6 shows a partial sectional side view of an exemplary embodiment of a semiconductor module according to the disclosure; and

FIG. 7 shows a partial sectional side view of an exemplary embodiment of a semiconductor module not being part of the disclosure.

### DETAILED DESCRIPTION

Exemplary embodiments of the present disclosure provide an improved semiconductor module and an improved method of manufacturing a semiconductor module.

For example, exemplary embodiments of the present disclosure provides a semiconductor module and a method of manufacturing a semiconductor module in which the manufacturing method is easier to perform with higher reproducibility and in which the semiconductor module has an improved reliability.

Exemplary embodiments of the disclosure relate to a semiconductor module, including a substrate, for example, formed of a ceramic insulator, and at least one metallic layer, for example, formed on the substrate, wherein the metallic layer includes a deepening (e.g., a depression) for placing and fixing a contact element, the contact element being at least partially “L”-shaped and including a first arm for fixing the contact element at the deepening, and a second arm for interconnecting the contact element, wherein the deepening has a horizontal dimension which is about ≦0.5 mm bigger than the horizontal dimension of the contact element.

According to an exemplary embodiment of the disclosure, the contact element can be placed, or aligned and arranged at the intended position, respectively, on the metallic layer at a preformed deepening or groove. As the deepening can be formed before performing the fixing process of the contact element on the metallic layer, the deepening can easily be arranged and located at a well defined position. Therefore, additionally to the deepening as such, the contact element can be located in a well defined and intended position.

Furthermore, due to the fact that the contact element is precisely located and furthermore held in place by the deepening, the contact element is avoided to slip, or move, respectively, in a horizontal plane on the metallic layer during a fixing process, for example during a welding process. Therefore, detrimental effects of the welding process can be avoided. Consequently, the semiconductor module according to the disclosure can be manufactured in a well defined and reproducible manner.

Due to the fact that the contact element can be in place by the deepening, a further and separate fixture which holds the contact element in place is not specified. For example, a separated holding and positioning device which holds the contact element in place can be omitted. This allows the semiconductor module according to an exemplary embodiment of the disclosure to be manufactured in an easy way without the conditions of a highly complex apparatus arrangement thereby being manufactured in a well reproducible manner.

The deepening is thus designed to hold the contact element in place, for example during a welding process, in the horizontal plane, the latter being defined by the plane of the metallic layer. It thus can prevent the contact element from moving in the horizontal plane. However, a limited movability of the contact element in the horizontal plane can be desired and is not problematic.

In detail, the deepening has a horizontal dimension which is about ≦0.5 mm bigger than the horizontal dimension of the contact element, for example, of the part of the contact element being fixed to the metallic layer. This allows a limited and, according to an exemplary embodiment of the disclosure, acceptable movability of the contact element in a horizontal plane thereby anyhow securing the contact element to be fixed substantially at the intended position. This feature, however, further simplifies placing the contact element in or at the deepening.

Consequently, the deepening is not adapted for a plurality of contact elements each having different sizes. Contrary thereto, providing that the deepening has a horizontal dimension which is about ≦0.5 mm bigger than the horizontal dimension of the contact element, the deepening is adapted to the defined contact element, thereby preventing a movability of the contact element, anyway allowing an easy and comfortable fixture of the latter.

Apart from that, the contact element can thus easily be located in the deepening thereby being located at the intended position in a simple manner. Furthermore, a deepening can easily be formed. For example, the deepening can be formed at a deposition step or the like of the metallic layer, or by structuring the metallic layer after deposition. Additionally, a deepening is an easy and in a secure way to avoid the contact element to move in a horizontal plane, for example during a welding process.

The contact element can thereby be any contact element which is appropriate for contacting the metallic layer. For example, the contact element can be such a contact element for internally contacting different circuits, or electric elements, respectively, of the semiconductor module. However, it is desirable that the contact element include a terminal for externally contacting the metallic layer, or the semiconductor module as such, respectively, to an external contacting device.

Additionally, the contact element is at least partially “L”-shaped and includes a first arm for fixing the contact element at the deepening, and a second arm for interconnecting the contact element with an external contact device, for example. Such a contact element is desirable for welding it at a deepening, or in a deepening, respectively. An at least partly “L”-shaped contact element according to an exemplary embodiment of the disclosure can thereby mean that at least the bottom part, where it is fixed to the metallic layer, is “L”-shaped. The first arm can thereby easily be located at the deepening and a pressing force can be exercised on the latter in a well-defined manner, thereby applying ultrasonic energy to weld the first arm, or the contact element, respectively, to the metallic layer. Due to the “L”-shaped form of the contact element, the second arm is located spaced apart from the metallic layer because of which it can easily be interconnected for example, with an external contact device.

According to the disclosure, an “L”-shaped form thereby can mean a design in which the first and second arms are arranged substantially rectangular with respect to each other. However, the contact element can deviate from the rectangular shape if the first arm lies substantially plane on the metallic layer, or at the deepening, respectively, and the second arm proceeds such, that its end is spaced apart from the plane of the metallic layer, so that an interconnection can easily be made.

According to an exemplary embodiment of the disclosure, a metallic layer can be a coating which is deposited on the substrate or on another layer, or it can be a small region of metallization which is deposited on the substrate or on another layer. However, the metallic layer can be any metallic or metallization layer or plate which is arranged in the semiconductor module and which shall be contacted. The metallic layer can be made, for example, of a material selected from the following materials: copper (Cu), gold (Au), silver (Ag), aluminium (Al) or alloys comprising Cu, Au, Ag and/or Al.

The semiconductor module can include any power semiconductor module known in the art. For example, a power semiconductor module including a power semiconductor device. Examples for power semiconductor devices include in a non limiting manner diodes, transistors, like Insulated Gate Bipolar Transistors (IGBT), and integrated circuits.

According to an exemplary embodiment of the present disclosure, the contact element includes a cooperation arrangement, for example at its first arm, for cooperating with the deepening. This furthermore improves the effect of the contact element being placed and hold at the intended position. The cooperation arrangement can be any suitable arrangement, if it is arranged to cooperate, or interact, respectively, with the deepening as will be apparent down below.

According to an exemplary embodiment according to the disclosure the deepening can have a depth of ≧100 μm. Such an arrangement can ensure that the contact element stays in the deepening, for example during a welding process, and is thus hold in place reliably. It is thus avoided that the contact element slips out of the deepening when fixing it to the metallic layer.

According to an exemplary embodiment according to the disclosure the deepening is at least partially surrounded by bevelled borders. This as well simplifies placing the contact element in or at the deepening.

In an exemplary embodiment of the disclosure, an intermediate layer can be arranged between the metallic layer and the substrate. This arrangement can lead to the advantage that the substrate is mechanically and/or thermally protected by the additional intermediate layer. Additionally, a metal layer with a deepening on one side can be easier to produce than a deepening in a substrate metallization itself. The additional layer, such as a metal layer, can be attached to the substrate in the same process step in which also the semiconductor chips are attached to the substrate.

Exemplary embodiments of the disclosure relate to a method of manufacturing a semiconductor module, including the step of bringing in contact a contact element and a metallic layer, the contact element being at least partially “L”-shaped and including a first arm for fixing the contact element at the deepening, and a second arm for interconnecting the contact element, and the metallic layer including a deepening for placing the contact element, wherein the deepening has a horizontal dimension which is about ≦0.5 mm bigger than the horizontal dimension of the contact element. The method includes pressing the contact element onto the metallic layer at the deepening and applying ultrasonic energy to the interface of the contact element and the metallic layer for welding the contact element onto the metallic layer.

According to an exemplary embodiment of the disclosure, the contact element is thus placed on the metallic layer by the deepening. This leads to the advantages like described above with respect to the semiconductor module according to an exemplary embodiment of the disclosure.

The contact element can be connected to the metallic layer by an ultrasonic welding process. A semiconductor module manufactured according to the disclosure does thus not exhibit disadvantages related to cycling. With respect to an exemplary embodiment of the present disclosure, cycling means an influence of periodically changing conditions, such as with respect to temperature and/or mechanical influence. This as well improves the reliability properties of a semiconductor module according to the disclosure.

The reliability of a semiconductor module according to an exemplary embodiment of the disclosure can be further improved by the fact that a welding connection can sustain temperatures of 200° C. or more. This additionally makes a semiconductor module manufactured according to the method according to an exemplary embodiment of the disclosure suitable even for high power applications.

Additionally, a semiconductor module can be manufactured according an exemplary embodiment without the specification of consumables like solder or bond wires. Furthermore, the manufacturing process can be performed without further plating or additional cleaning steps. This can lead to the advantage that the method according to an exemplary embodiment to the disclosure is advantageous with respect to the environmental point of view. Additionally, traditional working steps can be omitted making the method according to the exemplary embodiment of the disclosure time saving and thus cost saving.

By welding the contact element to the metallic layer, furthermore a highly conductive connection is formed. This makes the semiconductor module according to an exemplary embodiment of the disclosure being suitable for high power applications in which high amounts of electric currents have to be conducted through this connection. Consequently, the semiconductor module according to an exemplary embodiment of the disclosure can include a high power semiconductor module.

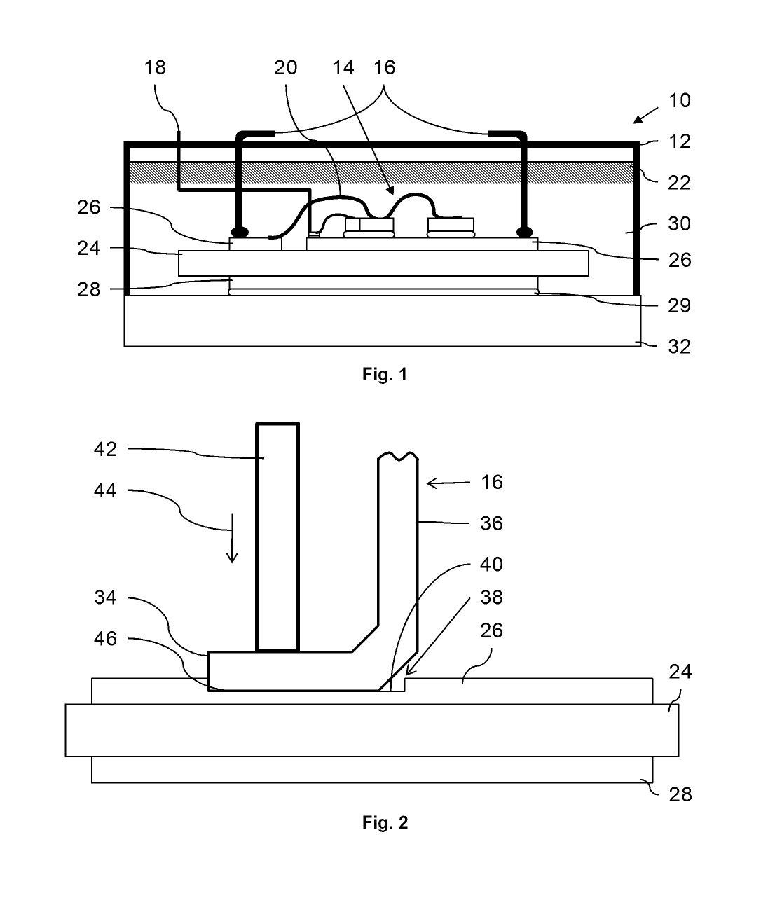

In FIG. 1, an arrangement of a semiconductor module 10 according to an exemplary embodiment of the disclosure is schematically shown. In detail, the internal structure of the semiconductor module 10 is described. The semiconductor module 10 includes a housing 12 in which at least one semiconductor device 14 is arranged. The semiconductor device 14 can, for example, be a power semiconductor device, such as an insulated gate bipolar transistor (IGBT), a diode, a metal oxide semiconductor field-effect transistor (MOSFET), or the like. According to FIG. 1, a diode and an IGBT are provided. The semiconductor device 14 or the plurality of semiconductor devices 14 are connectable via contact terminals, or contact elements 16, respectively, and via an auxiliary terminal 18, wherein the semiconductor device 14 can be bonded by aluminium bond wires 20.

As an insulator, a layer of epoxy 22 can be arranged above the semiconductor device 14. The semiconductor device 14 can further be arranged on a substrate 24, or wafer, respectively, which can be formed of a ceramic insulator, such as an aluminium nitride ceramic insulator. The contact elements 16 as well as the auxiliary terminal 18 are connected to the substrate 24 via a metallization, or metallic layer 26, respectively, for example, via a copper metallization. Additionally, the substrate 24 is connected to a further metallization 28, such as a copper metallization, at its bottom side, and to a base plate 32 via a solder 29. The remaining volume inside the housing 12 is filled, for example, with a silicone gel 30.

The connection between a contact element 16 and a metallic layer 26 is shown in detail in the following FIGS. 2 to 7 in which the same or comparable elements are referenced by the same reference signs.

In FIG. 2, the substrate 24 is shown together with the metallic layer 26 and the further metallization 28. To contact the metallic layer 26, a contact element 16 is provided.

The contact element 16 can be at least partially “L”-shaped, e.g., at least at its bottom side. It therefore can include a first arm 34 for fixing the contact element 16 at the metallic layer 26, and a second arm 36 for interconnecting it, for example, with an external contact device, the external contact device not being shown as such.

In order to place the contact element 16, or to locate it at the intended position, respectively, according to the disclosure, the metallic layer 26 includes a deepening 40 in the metallic layer 26 and can thus include a receptacle. Therefore, it is apparent that the contact element 16, or the first arm 34 of the contact element 16, respectively, can be fitted into the deepening 40 to be located at the intended position. The contact element 16, for example its first arm 34, can be fixed to the metallic layer 26. Therefore, one of the objects of the deepening 40 is to easily find the intended position of the contact element 16 on the metallic layer 26.

The deepening 40 can have a depth of ≧100 μm. This allows a secure fit of the contact element 16 in the deepening 40 to securely be hold in place.

Even if it is intended that the deepening 40 has as a second main objective to hold the contact element 16 in place during a fixing process, for example at a welding process, it can be appropriate that the deepening 40 has a horizontal dimension which is about ≦0.5 mm bigger than the horizontal dimension of the contact element 16, for example of the horizontal dimension of the first arm 34 of the contact element 16. This can improve arranging the contact element 16 in the deepening 40.

Once the contact element 16 is located in the deepening 40, it can be fixed on the metallic layer 26. This is described as follows, wherein it is noted that this can be performed independently from the special arrangement of the contact element 16 and/or deepening 40 and can thus be similarly performed in the exemplary embodiments of the disclosure according to the following Figures.

Fixing the contact element 16 to the metallic layer 26 can be part of a method of manufacturing a semiconductor module. After bringing in contact the contact element 16 and a metallic layer 26, the contact element 16 is pressed against the metallic layer 26. In the embodiment like described above, the contact element 16 is pressed against the metallic layer 26 via the first arm 34. This can be performed by pressing a welding tool 42 against the contact element 16, for example, against the first arm 34. This is schematically shown by the arrow 44 shown in FIG. 2.

The welding tool 42 can include a generator for generating ultrasonic waves, or ultrasonic energy, respectively. As an example, the welding tool 42 can include a sonotrode. Consequently, ultrasonic energy is applied to the interface 46 of the contact element 16 and the metallic layer 26. By virtue of ultrasonic energy, the contact element 16 and the metallic layer 26 can be connected to each other in that the contact element 16 is fixed to the metallic layer 26, or the deepening 40, respectively, by an ultrasonic welding process.

Due to the provision of the deepening 40, the contact element 16 can be securely held in place leading to the latter being fixed at the intended position.

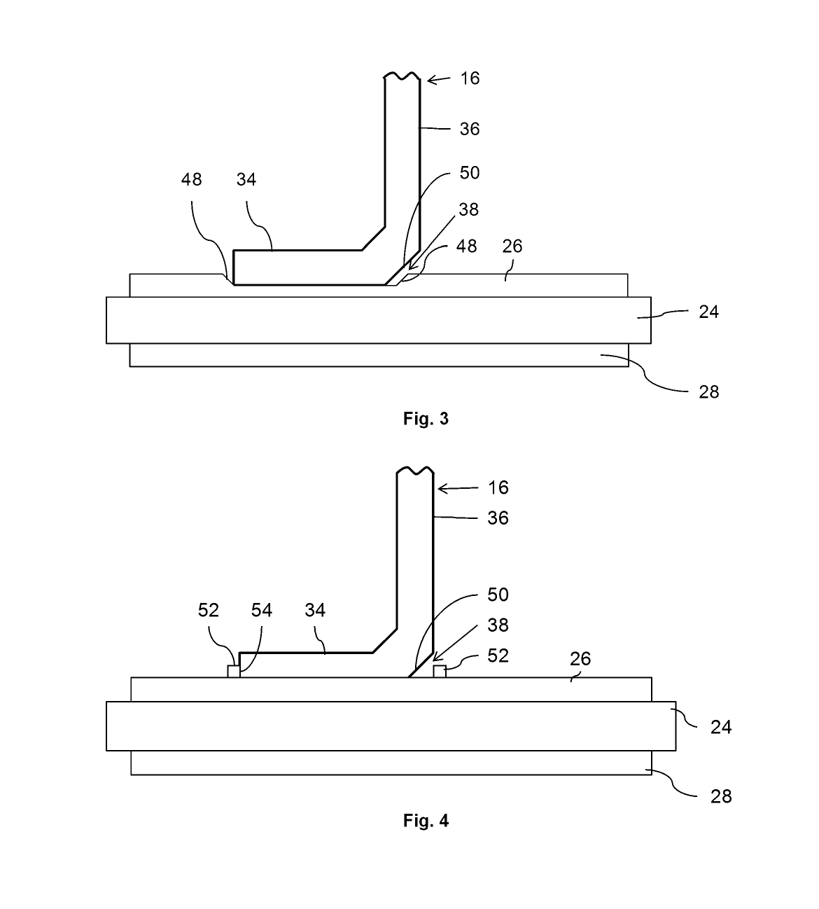

An exemplary embodiment of the present disclosure is shown in FIG. 3. According to FIG. 3, the deepening 40 can be at least partially surrounded by bevelled edges, or borders 48, respectively. The amount or degree of bevelling can be chosen according to the desired application. However, to secure the contact element 16 not to slip out of the deepening 40, it is desirable that the bevelling lies in a range of ≧45° (±10%) with respect to the horizontal plane, wherein the horizontal plane is defined by the plane of the metallic layer 26. It can furthermore be advantageous that the contact element 16 as well include a bevelled edge 50 at one or a plurality of sides. Desirably, these bevelled edges 50 can be adapted to the bevelled borders 48, so that the fitting of the contact element 16 on the metallic layer 26, or at the deepening 40, respectively is improved.

An exemplary embodiment of the disclosure is shown in FIG. 4. According to FIG. 4, a fixing device 38 includes at least one elevation 52 formed on the metallic layer 26. For example, the contact element 16 can be completely surrounded by elevations 52. Therefore, according to this embodiment, the fixing device 38 is formed completely on the metallic layer 26. This has the advantage that the metallic layer 26 is not weakened by the deepening 40 and thus can be advantageous for very thin metallic layers 26. The elevations 52 can in an exemplary manner be formed of at least one flat wire bond forming a stopper for the contact element 16. In this case, the fixing device 38 is very easy to prepare. The elevation can for example be formed at one or several sides of the intended position of the contact element. Additionally, it is possible to form the elevation on a location being located directly at the position of the contact element. In this case it is desirable that the contact element includes a cooperation device for cooperating, or interacting, respectively, with the elevation. The cooperation device can in this case be realized as a deepening in the contact element being adapted in its size and geometry to the elevation, or the fixing device, respectively. The contact element 16 can include one or more bevelled edges 50 and/or one or more rectangular edges 54. Additionally, the elevations 52 can include bevelled edges for facilitating placing the contact element 16 at the fixing device.

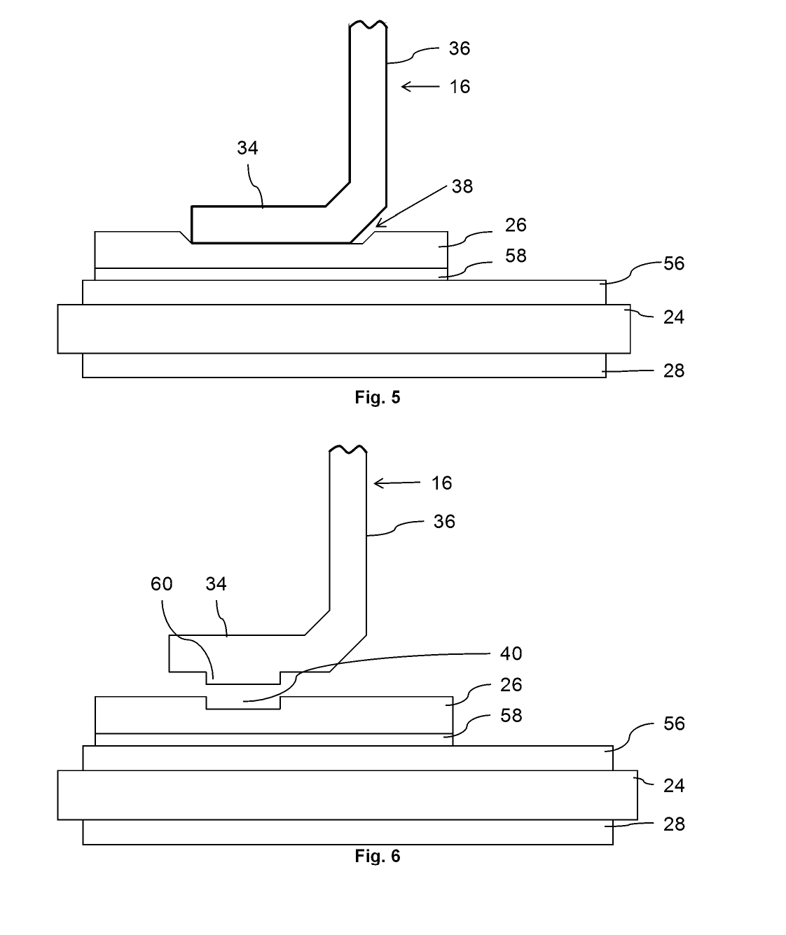

An exemplary embodiment according to the disclosure is shown in FIG. 5. This embodiment corresponds to the embodiment according to FIG. 3. However, the embodiment according to FIG. 5 includes the further feature, that an intermediate layer 56 is arranged between the metallic layer 26 and the substrate 24. The intermediate layer 56 can be any suitable layer, for example a metal layer, and it can be provided, for example, as a metal plate. The intermediate layer 56 can be attached to the metallic layer 26 by a solder 58 or a low-temperature bonding. It can furthermore be attached to the substrate 24 by any suitable way, for example, by a deposition process. According to FIG. 5, the intermediate layer 56 can be formed as a metallization on the substrate 24, whereas the metallic layer 26 including the deepening 40 can be formed as a metal plate.

The exemplary embodiment of the disclosure according to FIG. 6 again can include an intermediate layer 56 like described above. Additionally, according to FIG. 6, the metallic layer 26 can include a deepening 40 in the metallic layer 26. Additionally to the deepening 40, the contact element 16 includes a cooperation device, for example, at its first arm 34, for cooperating with the deepening 40. In detail, according to FIG. 6, the contact element 16 can include an elevation 60, for example, at the first arm 34. The elevation 60 and the deepening 40, can be adapted to each other with respect to size and geometry. Consequently, the elevation 60 of the contact element 16 serves as a fixing device for cooperating with the deepening 40. This allows the fit of the contact element 16 at the deepening 40 being much closer.

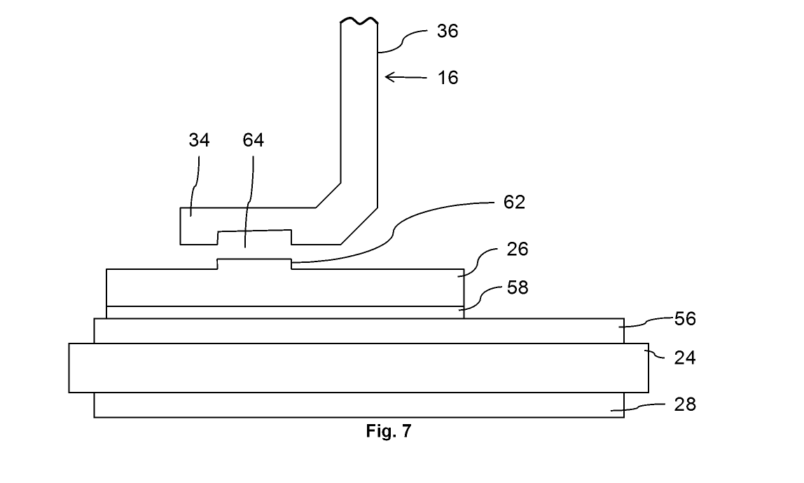

An exemplary embodiment of the present disclosure is shown in FIG. 7. The embodiment according to FIG. 7 corresponds to the embodiment of FIG. 6 with the difference, that the metallic layer 26 includes an elevation 62 as a fixing device 38, whereas the contact element 16, such as the first arm 34 of the contact element 16 includes a deepening 64 interacting with the fixing device 38. Again, the fixing device 38, e.g., the elevation 62, and the deepening 64 can be adapted to each other with respect to size and geometry.

It has to be noted that the features like described above are not limited to the described exemplary embodiments. For example, the arrangement of the fixing device 38 can be combined with and without an intermediate layer 56. Furthermore, combinations of different arrangements of the fixing device 38 are possible without leaving disclosure as such.

While the disclosure has been illustrated and described in detail in the drawings and foregoing description, such illustration and description are to be considered illustrative or exemplary and not restrictive; the disclosure is not limited to the disclosed exemplary embodiments. Other variations to be disclosed exemplary embodiments can be understood and effected by those skilled in the art in practicing the disclosure, from a study of the drawings and, the disclosure.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE SIGNS LIST

10 semiconductor module
12 housing
14 semiconductor device
16 contact element
18 auxiliary terminal
20 aluminium bond wires
22 epoxy
24 substrate
26 metallic layer
28 metallization
29 solder
30 silicone gel
32 base plate
34 first arm
36 second arm
38 fixing means
40 deepening
42 welding tool
44 arrow
46 interface
48 bevelled border
50 bevelled edge
52 elevation
54 rectangular edge
56 intermediate layer
58 solder
60 elevation
62 elevation
64 deepening

What is claimed is:

1. A semiconductor module, comprising:
a substrate formed of a ceramic insulator;
at least one metallic layer formed on the substrate; and
a contact element, the contact element being at least partially “L”-shaped and including a first arm for fixing the contact element at the deepening, and a second arm for interconnecting the contact element with an external device;
wherein the at least one metallic layer includes a deepening portion for placing and fixing the contact element, wherein the deepening portion has a horizontal dimension which is about ≦0.5 mm bigger than a horizontal dimension of the contact element.

2. The semiconductor module according to claim 1, wherein the semiconductor module is a power semiconductor module comprising:
a power semiconductor device including at least one of a diode, a transistor, and an integrated circuit.

3. The semiconductor module according to claim 1, wherein the contact element comprises:
a cooperation device having a first arm that cooperates with the deepening portion.

4. The semiconductor module according to claim 1, wherein the deepening portion has a depth of ≧100 μm.

5. The semiconductor module according to claim 1, wherein the deepening portion is at least partially surrounded by bevelled borders.

6. The semiconductor module according to claim 1, comprising:
an intermediate layer arranged between the at least one metallic layer and the substrate.

7. A method of manufacturing a semiconductor module, comprising:
bringing into contact a contact element and a metallic layer, the contact element being at least partially “L”-shaped and including a first arm for fixing the contact element at a deepening, and a second arm for interconnecting the contact element, wherein the metallic layer includes a deepening portion for placing the contact element, wherein the deepening has a horizontal dimension which is about ≦0.5 mm bigger than the horizontal dimension of the contact element;
pressing the contact element onto the metallic layer at the deepening; and
applying ultrasonic energy to the interface of the contact element and the metallic layer for welding the contact element onto the metallic layer.

8. A semiconductor module, comprising:
a substrate formed of a ceramic insulator;
at least one metallic layer formed on the substrate; and
a contact element having a first arm that extends in a first direction and second arm connected to the first arm that extends in a second direction, wherein the at least one metallic layer includes a depression configured to receive the first arm of the contact element, the depression having a horizontal dimension which is about ≦0.5 mm bigger than a horizontal dimension of the contact element.

9. The semiconductor module according to claim 8, wherein the second arm is configured to interconnect the contact element with an external device.

10. The semiconductor module according to claim 8, wherein the contact element comprises:
a cooperation device having a first arm that cooperates with the depression.

11. The semiconductor module according to claim 1, wherein the depression has a depth of ≧100 μm.

12. The semiconductor module according to claim 1, wherein the depression is at least partially surrounded by bevelled borders.

13. The semiconductor module according to claim 1, comprising:
an intermediate layer arranged between the at least one metallic layer and the substrate.
